(19) United States
(12) Patent Application Publication
(10) Pub. No.: US 2013/0044445 A1
(43) Pub. Date: Feb. 21, 2013

(54) MOUNTING APPARATUS FOR CIRCUIT BOARD

(71) Applicants: PO-WEN CHIU, Tu-Cheng (TW); ZHAN-YANG LI, Shenzhen City (CN); WEN-HU LU, Shenzhen City (CN)

(72) Inventors: PO-WEN CHIU, Tu-Cheng (TW); ZHAN-YANG LI, Shenzhen City (CN); WEN-HU LU, Shenzhen City (CN)

(73) Assignees: HON HAI PRECISION INDUSTRY CO., LTD., Tu-Cheng (TW); HONG FU JIN PRECISION INDUSTRY (ShenZhen) Co., LTD., Shenzhen City (CN)

(21) Appl. No.: 13/455,363

(22) Filed: Apr. 25, 2012

(30) Foreign Application Priority Data
Aug. 19, 2011 (CN) 201110239729.0

(51) Int. Cl. H05K 5/00

(52) U.S. Cl. 361/752

(57) ABSTRACT

A mounting apparatus for circuit board comprises a bottom or base board of a chassis, a securing structure and a reinforcing member. The securing structure is secured to the bottom board in which a securing hole is defined. The reinforcing member engages with the securing structure. A fixing member extends through a through hole defined in the circuit board to engage in the securing hole, for preventing any lateral movement of the circuit board.

### BACKGROUND

1. Technical Field

The present disclosure relates to mounting apparatuses, and particularly to a mounting apparatus for a circuit board.

2. Description of Related Art

A circuit board must be securely mounted in the chassis of a computer or a server system. The chassis includes a bottom board and two sidewalls located on the bottom board. The chassis defines a plurality of positioning holes. The circuit board may define a plurality of through holes corresponding to the positioning holes in the chassis and a plurality of screws will be inserted into the through holes and the positioning holes to secure the circuit board to the chassis. However, the plurality of through holes may influence layout of the circuit board and prevent an optimum layout, and further prevent optimum use of the receiving space in the chassis.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and a circuit board.

FIG. 2 is an exploded, cutaway, isometric view of a chassis, a securing structure and a reinforcing member of FIG. 1.

FIG. 3 is an isometric view of the reinforcing member of FIG. 1.

FIG. 4 is a partly assembled view of the mounting apparatus and the circuit board of FIG. 1.

FIG. 5 is an assembled view of the mounting apparatus and the circuit board of FIG. 1.

FIG. 6 is a cross-sectional view of the mounting board and the circuit board of FIG. 5, taken along the line VI-VI.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

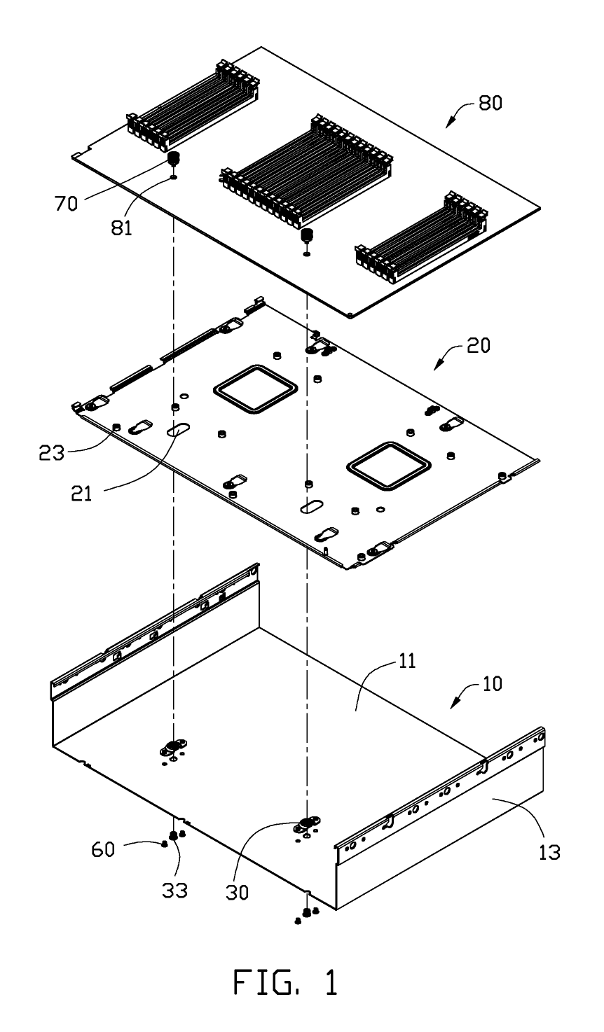

Referring to FIG. 1, an embodiment of a mounting apparatus, configured to secure a circuit board 80, includes a chassis 10, a supporting plate 20, two securing structures 30 and two reinforcing members 40.

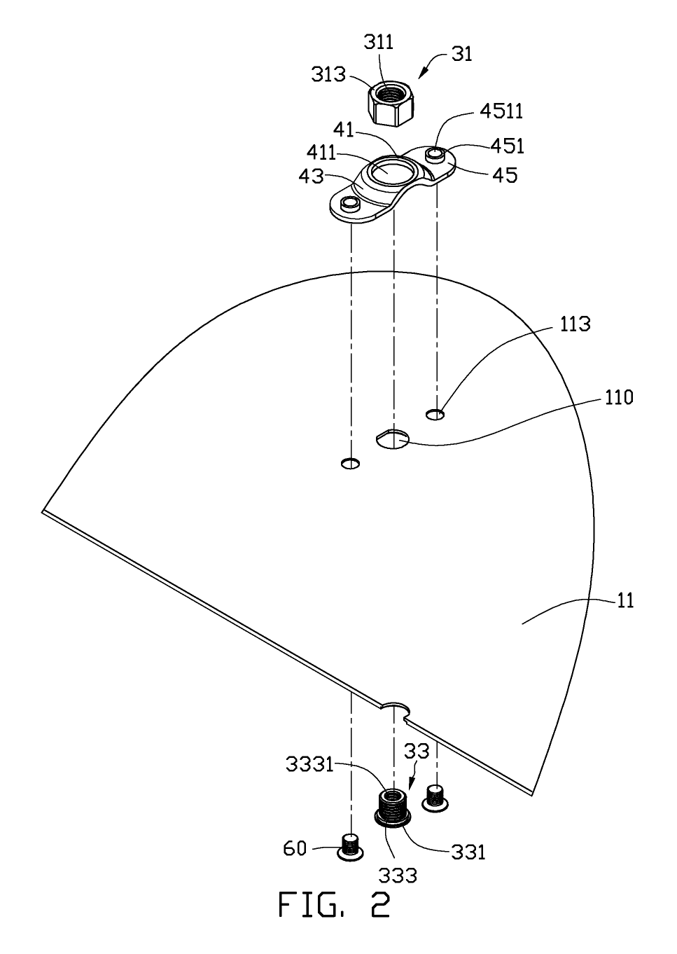

The chassis 10 includes a bottom board 11 and two sidewalls 13. The two sidewalls 13 are parallel to each other. In one embodiment, each of the two sidewalls 13 is substantially perpendicular to the bottom board 11. Referring to FIG. 2, the bottom board 11 defines a positioning hole 110 and two installation holes 113. The two installation holes 113 are located on two sides of the positioning hole 110. In one embodiment, a line (not shown) cutting diametrically through the two installation holes 113 and the positioning hole 110 between them is substantially parallel to the two sidewalls 13.

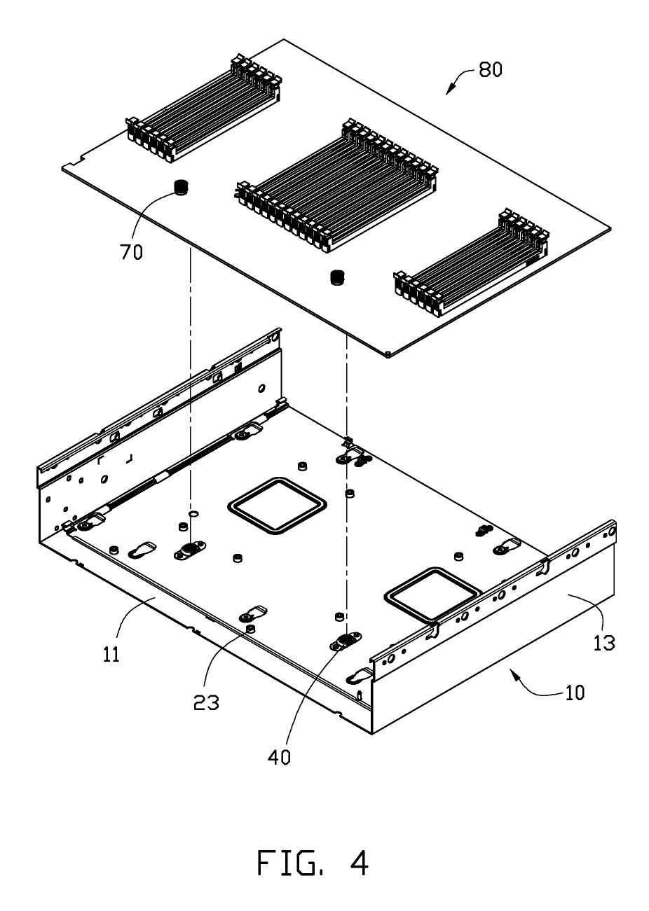

Referring to FIGS. 1 and 4, the supporting plate 20 is secured to the bottom board 11 by fasteners (not shown), such as screws. The supporting plate 20 defines an opening 21. A plurality of pillars 23 is located on the supporting plate 20 for supporting the circuit board 80.

Referring to FIG. 2, each securing structure 30 includes a first securing member 31 and a second securing member 33. The first securing member 31 defines a threaded hole 311 for receiving the second securing member 33. In one embodiment, the first securing member 31 is substantially columnar. The second securing member 33 includes a stopping portion 331 and an engaging portion 333 extending from the stopping portion 331. The engaging portion 333 defines a securing hole 3331.

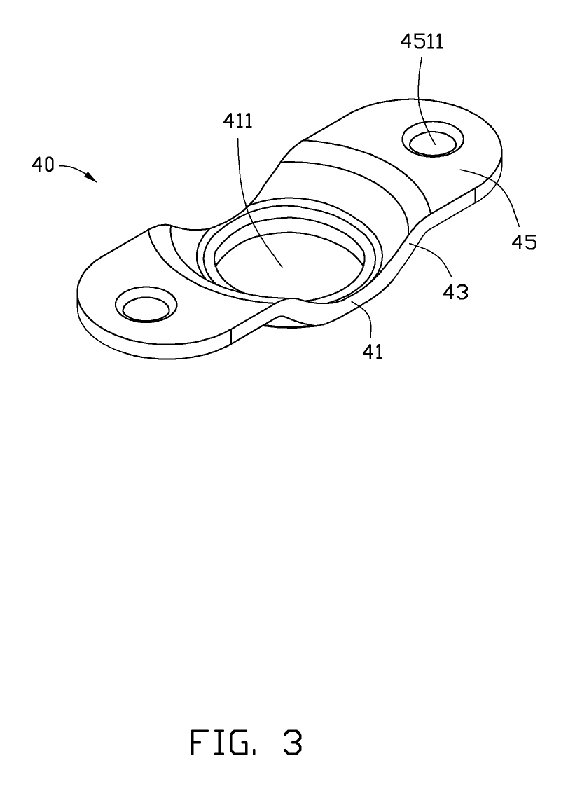

Referring to FIG. 3, the reinforcing member 40 includes a reinforcing portion 41, two connecting portions 43 and two limiting portions 45. The reinforcing portion 41 defines a receiving hole 411. The two connecting portions 43 extend from opposite sides of the reinforcing portion 41. In one embodiment, a first obtuse angle is defined between each connecting portion 43 and the reinforcing portion 41. The two limiting portions 45 extend from the two connecting portions 43. In one embodiment, a second obtuse angle is defined between each limiting portion 45 and each connecting portion 43. A protrusion 451 is located on each limiting portion 45. A limiting hole 4511 is defined in the limiting portion 45 extending through the protrusion 451.

Referring to FIG. 1, the circuit board 80 defines a through hole 81 to match each securing hole 3331.

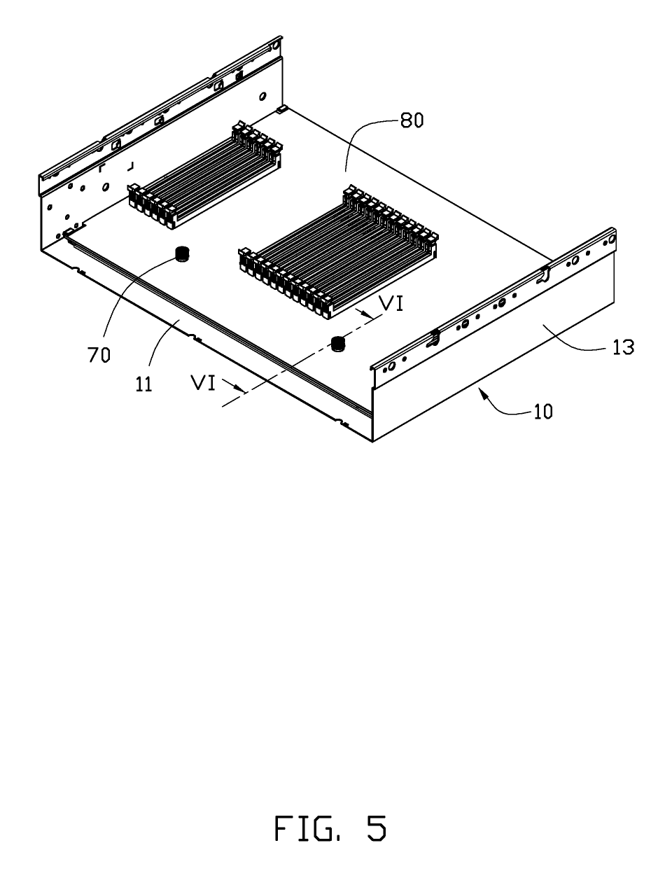

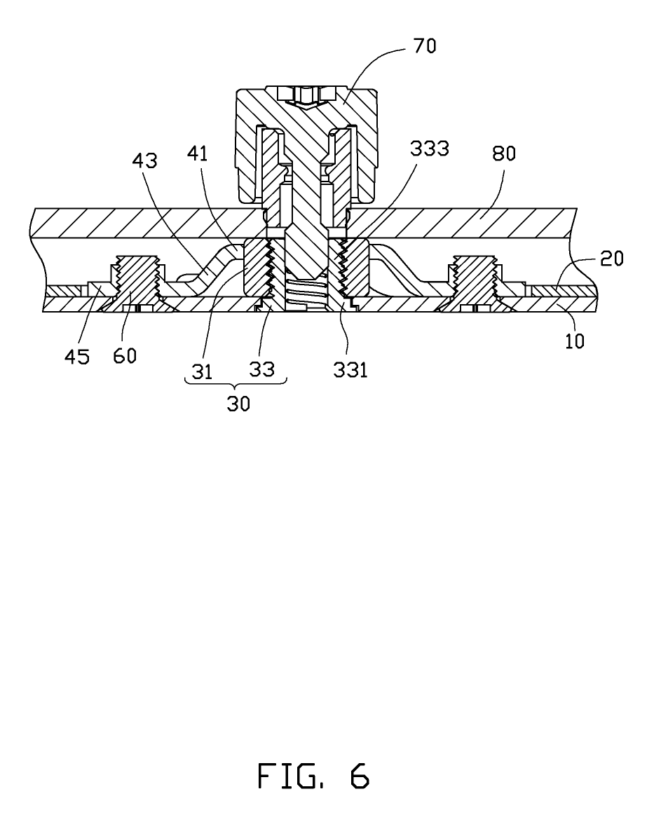

Referring to FIGS. 5-6, in assembly, the securing structures 30 are installed on the bottom board 11. The securing structures 30 are all installed in the same manner, so only the installation of one is described. The first securing member 31 rests on the bottom board 11, and the threaded hole 311 is aligned with the positioning hole 110. The second securing member 33 is inserted into the positioning hole 110 and engaged in the threaded hole 311. The receiving hole 411 allows each reinforcing member 40 to be assembled onto the securing structure 30. The reinforcing member 40 is rotated around the central axis so that each of the two limiting holes 4511 is aligned with each of the two installation holes 113. Locking members 60 engage into the two installation holes 113 and the two limiting holes 4511, and the reinforcing member 40 is thereby installed on the chassis 10.

In assembly of the circuit board 80, the circuit board 80 is placed on the pillars 23 and the reinforcing portion 41. Each through hole 81 is aligned with each securing hole 3331, and a fixing member 70 is inserted into the through hole 81 and the securing hole 3331. The circuit board 80 is thereby secured to the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for a circuit board comprising:
a chassis comprising a bottom board and two sidewalls located on two opposite sides of the bottom board;
a securing structure secured to the bottom board, the securing structure defining a securing hole; and
a reinforcing member engaged with the securing structure, the reinforcing member secured to the bottom board, a fixing member extending through a through hole, defined in the circuit board, to engage in the securing hole, for preventing the circuit board from moving relative to the bottom board along a direction parallel to the two sidewalls.

2. The mounting apparatus of claim 1, wherein the bottom board defines a positioning hole, the securing structure comprises a first securing member and a second securing member, and the second securing member extends through the positioning hole to engage with the first securing member.

3. The mounting apparatus of claim 2, wherein the reinforcing member comprises a reinforcing portion with a receiving hole, and the securing structure is engaged in the receiving hole.

4. The mounting apparatus of claim 3, wherein the reinforcing member further comprises two connecting portions extending from two opposite sides of the reinforcing portion, and a first obtuse angle is defined between each connecting portion and the reinforcing portion.

5. The mounting apparatus of claim 4, wherein the reinforcing member further comprises two limiting portions correspondingly extending from the two connecting portions, and a second obtuse angle is defined between each of the two limiting portions and corresponding one of the two connecting portions.

6. The mounting apparatus of claim 5, wherein each of the two limiting portions defines a limiting hole; the bottom board defines two installation holes corresponding to the limiting holes of the two limiting portions; and two locking members are inserted into the two installation holes and the corresponding limiting holes, to secure the reinforcing member to the bottom board.

7. The mounting apparatus of claim 6, wherein a line cutting diametrically through the two installation holes and the positioning hole between them is substantially parallel to the two sidewalls.

8. The mounting apparatus of claim 7, wherein a protrusion is located on each of the two limiting portions, and each limiting hole extends through the corresponding one of the protrusions.

9. The mounting apparatus of claim 1, wherein the mounting apparatus further comprises a supporting plate secured to the bottom board, the supporting plate defines an opening, and the securing structure and the reinforcing member are received in the opening.

10. The mounting apparatus of claim 9, wherein a plurality of pillars is located on the supporting plate for supporting the circuit board.

11. A mounting apparatus for a circuit board comprising:
a chassis comprising a bottom board;
a supporting plate secured to the bottom board, the supporting plate defining an opening;
a securing structure secured to the bottom board, the securing structure defining a securing hole; and
a reinforcing member engaged with the securing structure, the reinforcing member secured to the bottom board and received in the opening, and a fixing member extending through a through hole defined in the circuit board, to engage in the securing hole, for preventing the circuit board from moving relative to the bottom board along a direction perpendicular to the bottom board.

12. The mounting apparatus of claim 11, wherein the bottom board defines a positioning hole, the securing structure comprises a first securing member and a second securing member, and the second securing member extends through the positioning hole, to engage with the first securing member.

13. The mounting apparatus of claim 12, wherein the reinforcing member comprises a reinforcing portion with a receiving hole, and the securing structure is engaged in the receiving hole.

14. The mounting apparatus of claim 13, wherein the reinforcing member further comprises two connecting portions correspondingly extending from two opposite sides of the reinforcing portion, and a first obtuse angle is defined between each of the two connecting portion and the reinforcing portion.

15. The mounting apparatus of claim 14, wherein the reinforcing member further comprises two limiting portions extending from the two connecting portions, and a second obtuse angle is defined between each limiting portion and each connecting portion.

16. The mounting apparatus of claim 15, wherein each of the two limiting portions defines a limiting hole; the bottom board defines two installation holes corresponding to the limiting holes of the two limiting portions; and two locking members are located in the two installation holes and the corresponding limiting holes, to secure the reinforcing member to the bottom board.

17. The mounting apparatus of claim 16, wherein the chassis further comprises two sidewalls substantially perpendicular to the bottom board, and a line cutting diametrically through the two installation holes and the positioning hole between them is substantially parallel to the two sidewalls.

18. The mounting apparatus of claim 17, wherein a protrusion is located on each of the two limiting portions, and each limiting hole extends through the corresponding one of the protrusions.

19. The mounting apparatus of claim 11, wherein a plurality of pillars is located on the supporting plate for supporting the circuit board.
